(19) United States
(12) Patent Application Publication
(10) Pub. No.: US 2007/0164789 A1
(43) Pub. Date: Jul. 19, 2007

(54) High Speed Level Shift Circuit with Reduced Skew and Method for Level Shifting

(75) Inventors: Geeta Panjwani, New Delhi (IN); Aparna Jandhyala, Bangalore (IN); Derwin M. Mattos, San Mateo, CA (US)

Correspondence Address: DAFFER MCDANIEL LLP, P.O. BOX 684908, AUSTIN, TX, 78768, US

(73) Assignee: CYPRESS SEMICONDUCTOR CORP., San Jose, CA (US)

(21) Appl. No.: 11/623,844

(22) Filed: Jan. 17, 2007

Related U.S. Application Data
(60) Provisional application No. 60/743,755, filed on Mar. 24, 2006.

(30) Foreign Application Priority Data
Jan. 17, 2006 (IN) 72/CHE/2006

(51) Int. Cl. H03K 19/0175

(52) U.S. Cl. 326/80

(57) ABSTRACT

An improved level shift circuit and method for level shifting is disclosed herein. In general, the improved level shift circuit adds a pulse generator, a feedback transistor and a latch to a conventional cross-coupled level shift circuit configuration. The pulse generator and feedback transistor are configured for reducing a fall delay associated with the level shift circuit. For example, the pulse generator is coupled for supplying a short duration feedback pulse to the feedback transistor during a first time period when input and output signals of the level shift circuit transition to a LOW state. The feedback pulse reduces the fall delay by increasing the speed with which the output signal is pulled LOW. The latch is coupled for preventing the feedback signal from floating when at least one of the input and output signals is HIGH. An integrated circuit comprising at least one level shift circuit is also contemplated herein.

### PRIORITY CLAIM

This application claims priority to Indian Application No. 72/CHE/2006 filed Jan. 17, 2006 and U.S. Provisional Application No. 60/743,755 filed Mar. 24, 2006.

### BACKGROUND OF THE INVENTION

1. Field of the Invention

This invention relates generally to integrated circuits, and in particular, to a high speed level shift circuit with reduced skew. More specifically, the invention provides an improved level shift circuit configured for reducing rise and fall propagation delays, as well as the amount of mismatch (i.e., skew) between such delays.

2. Description of the Related Art

The following descriptions and examples are given as background only.

Some I/O standards may require an integrated circuit (IC) to interface with external voltages that are significantly higher than the internal voltages used within the IC. For example, advancements in integrated circuit process technology have allowed the feature size of a transistor to be reduced, thereby enabling low-voltage, high speed operation and high density layouts. In particular, low-voltage transistors have been developed having reduced feature sizes (e.g., thinner gate oxides) and smaller voltage swings, thereby increasing the speed with which the transistor is able to switch between “on” and “off” states. However, reducing the feature size also reduces the transistor's gate oxide voltage tolerance, or the maximum voltage level that may be supplied to the transistor gate without causing gate oxide degradation or breakdown. Performance issues arise when the gate oxide begins to degrade, with circuit failure occurring when the gate oxide reaches breakdown. For this reason, interface circuits are often necessary to interface the low-voltage transistors used within the IC to high voltage systems coupled thereto. This is an important challenge in input/output (I/O) design.

In order to provide compatibility with higher voltage systems, an interface circuit may be incorporated within the input/output (I/O) portion of an integrated circuit (IC) for translating higher voltage signals into lower voltage signals, and vice versa. For example, an interface circuit may include a voltage translator, level shift circuit or level clipping circuit within the signal path preceding the input/output buffer of the I/O. In some cases, a level shift circuit may be included within the interface circuit to translate signals from relatively low core supply levels to relatively high I/O supply levels, and vice versa. High speed ICs require fast level shift circuits with low rising and falling propagation delays. In addition, tight timing budgets in the I/O portions of the IC require reduced mismatch (i.e., skew) between rise/fall propagation delays.

One embodiment of a conventional level shift circuit (100) that may be included within an interface circuit for translating signals from relatively low core supply levels to relatively high I/O levels is shown in FIG. 1. Level shift circuit 100 generally includes a pair of pull-down transistors (MN1, MN2) and a pair of pull-up transistors (MP1, MP2). Each of the pull-up transistors is coupled in series with a different one of the pull-down transistors between a power supply voltage (V_{PS1}) and ground (Vgnd). The control terminals of the pull-up transistors are cross-coupled between the output nodes (OUT, OUTB) of the level shift circuit. In some cases, a pair of differential input signals (IN, INB) may be supplied to the control terminals of the pull-down transistors (MN1, MN2). In other cases, an inverter (I1) may be coupled between the control terminals of the pull-down transistors, as illustrated in FIG. 1. As such, inverter I1 may be included for inverting a single-ended input signal (IN) supplied to one of the pull-down transistors (e.g., MN1) and forwarding the inverted input signal (INB) to the other pull-down transistor (e.g., MN2). As described in more detail below, the power supply voltage (V_{PS1}) may be a relatively high voltage level consistent with the high voltage transistors included within an I/O portion of the IC.

The conventional level shift circuit shown in FIG. 1 operates in the following manner. When the IN signal transitions from a logic LOW state to a logic HIGH state, the OUTB node discharges to ground (Vgnd) through pull-down transistor MN1. This turns ON pull-up transistor MP2, which charges the OUT node to a logic HIGH state by pulling the OUT node up towards the voltage level of the power supply (V_{PS1}). When the IN signal transitions from a logic HIGH state to a logic LOW state, the INB signal transitions from a logic LOW state to a logic HIGH state, which turns ON pull-down transistor MN2 to discharge the OUT node to ground.

As noted above, the illustrated embodiment may be configured for translating signals from relatively low core supply levels to relatively high I/O levels. For example, level shift circuit 100 may be configured for translating input signals (IN, INB) with relatively low voltage swings (e.g., about 1.2V to about 1.8V) into output signals (OUT, OUTB) with relatively high voltage swings (e.g., about 2.5V to about 3.3V). In general, a level shift circuit may be configured for shifting the voltage level of an incoming signal to that of an output signal. For example, common power supply levels include 1.2V, 1.8V, 2.5V, 3.3V, and 5.0V. For the purpose of illustration, assume that a level shift circuit is supplied with a relatively low power supply of about 1.2V and a relatively high power supply of about 3.3V. In such a case, the level shift circuit may increase a relatively low voltage input signal (e.g., within the range of about 1.1V to about 1.3V) into a relatively high voltage output signal (e.g., within the range of about 2.4V to about 3.6V). In order to accommodate higher swing output signals, level shift circuit 100 may be implemented with high voltage transistors having threshold voltages (Vt) significantly greater than 1V.

Disadvantages of the conventional level shift circuit (100) shown in FIG. 1 include large rise and fall propagation delays, due to limited overdrive, and large skew mismatch. For example, pull-down transistors MN1 and MN2 may have very limited overdrive when translating between, e.g., 1.35V core supply levels to 3.6V I/O supply levels. Because of such limited overdrive, the rise and fall propagation delays are very high (e.g., on the order of ns), causing speed limitations as well as large skews between the delays. In one example, level shift circuit 100 may demonstrate a maximum delay of about 1.65 ns and a skew that varies between about 40 ps to about 540 ps. These disadvantages become severe for even larger differences in core/IO supplies (e.g., translating between 1.2V core supply levels to 3.3V I/O supply levels), as the high voltage transistors used within the IOs have threshold voltages comparable to the core supply.

Therefore, it would be desirable to provide an improved level shift circuit with reduced rise and fall propagation delays and reduced skew between rise and fall propagation delays.

### SUMMARY OF THE INVENTION

The following description of various embodiments of level shift circuits, integrated circuits and methods of level shifting is not to be construed in any way as limiting the subject matter of the appended claims.

According to one embodiment, a level shift circuit is provided herein with reduced rise and fall propagation delays, as well as reduced skew between rise/fall delays. In general, the level shift circuit may include a first input transistor coupled in series with a first cross-coupled transistor between a power supply and a ground supply; a second input transistor coupled in series with a second cross-coupled transistor between the power supply and the ground supply; and an output node arranged between the second input and cross-coupled transistors. The first input transistor may be coupled for receiving a first input signal supplied to the level shift circuit, the second input transistor may be coupled for receiving a second input signal supplied to (or produced by) the level shift circuit, and the output node may be coupled for receiving an output signal generated by the level shift circuit.

Preferably, the level shift circuit may also include a feedback transistor and a pulse generator for reducing a fall delay associated with the level shift circuit. For example, the feedback transistor may be coupled for receiving a feedback pulse from the pulse generator. As described in more detail below, the feedback pulse may be adapted to reduce the fall delay by enabling the feedback transistor to assist in the pull-down action. The pulse generator may be configured for generating the feedback pulse only when the input signal supplied to the first input transistor (i.e., the first input signal) and the output signal generated by the level shift circuit are both logic low.

Preferably, a rise delay associated with the level shift circuit may be reduced by configuring the first and second cross-coupled transistors, such that the first cross-coupled transistor is substantially smaller than the second cross-coupled transistor. Decreasing the size of the first cross-coupled transistor reduces the rise delay by offering less resistance when the first input transistor attempts to pull the output signal down to the logic level.

In one embodiment, the pulse generator may include a first, a second and a third pulse generator transistor coupled in series between the power supply and the ground supply, and an output terminal, which is arranged between the first and second pulse generator transistors for receiving the feedback pulse generated there between. In particular, the pulse generator may be coupled to a control terminal of the second input transistor for receiving the second input signal, and to the output node for receiving the output signal. More specifically, a control terminal of the second pulse generator transistor may be coupled for receiving the second input signal. Control terminals of the first and third pulse generator transistors may be coupled for receiving the output signal. The output terminal of the pulse generator may then be coupled to a control terminal of the feedback transistor for supplying the feedback pulse thereto. In this manner, the pulse generator may be configured for asserting the feedback pulse, and thus, activating the feedback transistor when the output signal and the first input signal are both logic low and the second input signal is logic high.

Preferably, a latch may also be included within the level shift circuit to prevent the feedback node (i.e., the output terminal of the pulse generator) from floating in an undefined state when at least one of the input and output signals is logic high. For example, the latch may be coupled between a control terminal of the first input transistor and the output terminal of the pulse generator.

In one embodiment, the latch may include a first latch transistor coupled in series with a second latch transistor between the power supply and the ground supply. The latch may also include an inverter having an input coupled between the first and second latch transistors, and an output coupled to the output terminal of the pulse generator. More specifically, a control terminal of the first latch transistor may be coupled to the output terminal of the pulse generator, whereas a control terminal of the second latch transistor may be coupled to the control terminal of the first input transistor. In this manner, the latch may be configured for de-asserting the feedback pulse, and thus, deactivating the feedback transistor when at least one of the output signal and the first input signal is logic high.

According to another embodiment, a method for level shifting is contemplated herein. For example, the method may include supplying an input signal to a level shift circuit and generating an output signal within the level shift circuit. The method may also include generating a feedback signal by NANDing the output signal with an inverted version of the input signal; and supplying the feedback signal to a control terminal of a feedback transistor of the level shift circuit, which is coupled to a control terminal of a pull-up transistor of the level shift circuit.

During a first time period, the input and output signals may transition from a logic high state to a logic low state. During this time, the method may generate a short duration pulse within the level shift circuit to increase a speed with which the output signal transitions from high to low. For example, the short duration pulse may be supplied to the control terminal of the feedback transistor to activate the feedback transistor and increase a control voltage supplied to the pull-up transistor. This deactivates the pull-up transistor faster, thereby increasing the speed with which a pull-down transistor of the level shift circuit can pull the output signal low. As noted above, however, the step of generating a feedback signal may include generating the short duration pulse only when the output signal and the input signal are both logic low.

During a second time period, the input and output signals may transition from the logic low state to the logic high state. During this time, the method may include forcing the feedback signal to the logic high state to de-activate the feedback transistor, prevent a feedback node of the level shift circuit from floating in an undefined state and reduce static power consumption of the level shift circuit.

According to another embodiment, an integrated circuit (IC) is contemplated herein. For example, the integrated circuit may include at least one interface circuit configured for converting a first signal level into a second signal level, the second signal level being substantially different from the first signal level. In order to perform the necessary signal translation, the interface circuit may include at least one level shift circuit, similar to the level shift circuit described above.

For example, the at least one level shift circuit may include a pair of pull-down transistors, at least one of which is coupled for receiving an input signal at the first signal level; and a pair of pull-up transistors, each coupled in series with a different one of the pair of pull-down transistors between a first power supply and ground. The at least one level shift circuit may also include an output node arranged between one of the serially-coupled pull-up and pull-down transistors for generating an output signal at the second signal level.

Preferably, the at least one level shift circuit may also include a feedback transistor, a pulse generator and a latch. As noted above, the feedback transistor may be coupled for reducing a fall delay associated with the level shift circuit by receiving a short duration pulse, which is adapted to deactivate one of the pull-up transistors faster. The pulse generator is coupled to the feedback transistor and configured for generating the short duration pulse only when the input signal and the output signal are both logic low. The latch is coupled between the pulse generator and the feedback transistor for supplying a logic high signal to the feedback transistor when at least one of the input and output signals is logic high.

### BRIEF DESCRIPTION OF THE DRAWINGS

Other objects and advantages of the invention will become apparent upon reading the following detailed description and upon reference to the accompanying drawings in which:

FIG. 1 is a circuit diagram illustrating a conventional cross-coupled level shift circuit;

FIG. 2 is a circuit diagram illustrating an improved level shift circuit, according to one embodiment of the invention;

FIG. 3 is a graph illustrating an exemplary operation of the improved level shift circuit shown in FIG. 2;

FIG. 4 is a circuit diagram illustrating one embodiment of the improved level shift circuit in more detail;

FIG. 5 is a flowchart illustrating an exemplary method for level shifting; and

FIG. 6 is a block diagram illustrating an exemplary integrated circuit (IC) including the improved level shift circuit within one or more interface circuits arranged around the periphery of the IC.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF PREFERRED EMBODIMENTS

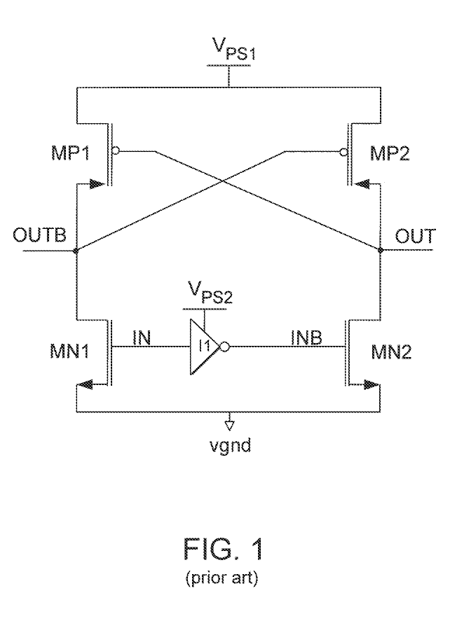

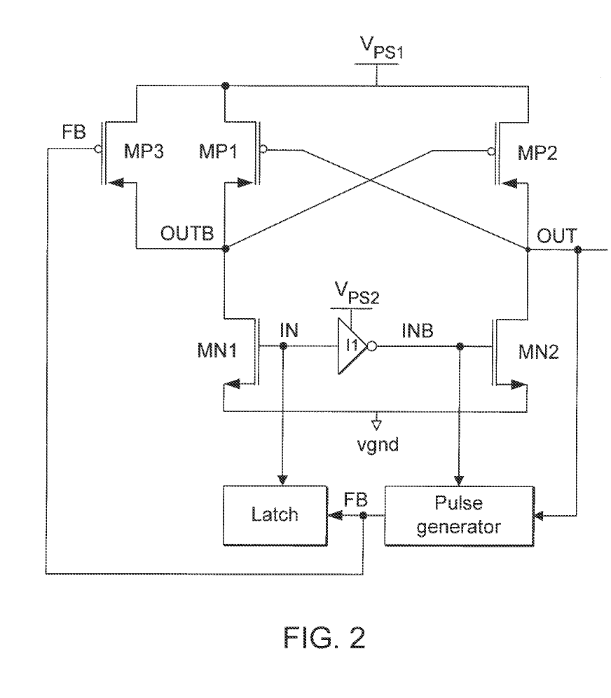

FIG. 2 shows a circuit diagram of an improved level shift circuit, according to one embodiment of the invention. As described in more detail below, the improved level shift circuit is configured to operate at very high speeds and with reduced skew. Compared to the conventional solution shown in FIG. 1, the improved level shift circuit shown in FIG. 2 may, in some cases, reduce rise/fall propagation delays from about 1.65 nanoseconds (ns) to about 400 picoseconds (ps) over a voltage range of about 1.35V to about 3.6V. The improved level shift circuit may also reduce skew between rise and fall transitions from about 540 ps (worst case) to about 200 ps (worst case), when compared to the conventional solution.

Of course, one skilled in the art would recognize that these values may be dependent on a variety of process and design factors including, but not limited to, the particular process technology used, I/O and core voltage signal level range, operating frequency, and the turn-off action provided by the feedback circuit (discussed below), among others. Therefore, the exemplary values provided above for propagation delay and skew should not be considered to limit the invention in any way. Furthermore, one skilled in the art would recognize how the improved level shift circuit could be adapted for level shifting between substantially different voltage levels. In some cases, the improved level shift circuit may provide even greater benefits when a larger difference exists between core and I/O voltage supplies (e.g., when translating 1.2V core supply levels to 3.3V I/O supply levels, or vice versa). As such, the improved level shift circuit is not limited to level shifting between the exemplary voltage range discussed herein of about 1.35V to about 3.6V.

The improved solution, shown in FIG. 2, generally comprises a feedback driver and a feedback device. As described in more detail below, the feedback driver forms a NAND function and uses the inverted input signal (INB) and the output signal (OUT) as inputs. The improved solution also includes a logic hold circuit, which serves to complete the NAND function by providing a pull-up function for the feedback path. When the IN signal transitions to a logic LOW state, the feedback driver sends a short duration logic low pulse (FB) to the control terminal of the feedback device to pull the OUTB node up towards the power supply voltage (V_{PS1}). This speeds up the fall transition by enabling the OUT node to discharge as quickly as possible. When the IN signal transitions to a logic HIGH state, the logic hold circuit forces the feedback signal (FB) signal to logic HIGH to prevent the feedback node from floating and consuming static power.

As used herein, a logic HIGH state refers to a signal level at, or close to, the upper threshold of the signal swing. A logic LOW state refers to a signal level at, or close to, the lower threshold of the signal swing. For example, the IN signal may swing between a logic LOW state of about 0V and a logic HIGH state of about 1.35V. In addition, the OUT signal may swing between a logic LOW state of about 0V and a logic HIGH state of about 3.6V. However, because the voltage values constituting logic HIGH and LOW states are swing dependent, they are not limited to the exemplary values provided herein. Other voltage values may be used to describe logic HIGH and LOW states when translating between substantially different voltage ranges.

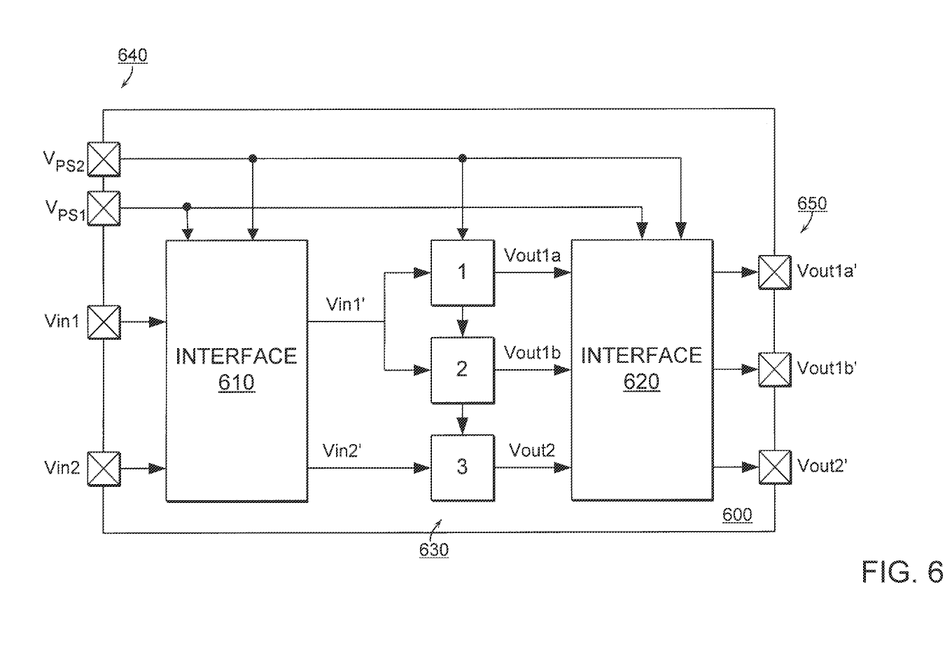

In general, level shift circuit 200 may be included within an interface circuit (as shown, e.g., in FIG. 6) for translating relatively small swing signals (e.g., signals generated at lower core supply levels) to relatively high swing signals (e.g., signals generated at higher I/O supply levels). For example, level shift circuit 200 may be configured for translating internal signals generated within an integrated circuit (IC) using a 1.35V power supply voltage to external signals usable within an I/O portion of the IC having a 3.6V power supply voltage. In some cases, level shift circuit 200 may perform level shifting by configuring a plurality of complementary metal oxide semiconductor (CMOS) transistors, as shown in FIG. 2. However, one skilled in the art would recognize how level shift circuit 200 could be modified to use other process technologies (e.g., BiCMOS and any other technology containing CMOS).

According to one embodiment, level shift circuit 200 includes a pair of pull-down NMOS transistors (MN1, MN2) and a pair of pull-up PMOS transistors (MP1, MP2). Each of the pull-up transistors is coupled in series with a different one of the pull-down transistors between a first power supply (V_{PS1}) and ground (V_{GND}). The control terminals (i.e., the gate terminals) of the pull-down transistors are coupled for receiving a pair of differential input signals (IN, INB). As such, pull-down transistors (MN1, MN2) may be otherwise referred to herein as “input transistors.” In some cases, transistors MN1, MN2, MP1 and MP2 may be implemented with high voltage transistors for translating lower swing input signals (IN, INB) into higher swing output signals (OUT, OUTB).

In some cases, differential input signals (IN, INB) may be directly supplied to the gate terminals of the pull-down transistors (e.g., from a differential signal source). In other cases, an inverter (I1) may be coupled between the gate terminals of the pull-down transistors, as shown in FIG. 2. As such, inverter I1 may be included for inverting a single-ended input signal (IN) supplied to one of the pull-down transistors (e.g., MN1) and forwarding the inverted input signal (INB) to the other pull-down transistor (e.g., MN2). In some cases, inverter I1 may be implemented with low voltage transistors. As shown in FIG. 2, the low voltage transistors used within inverter I1 may be coupled to a second power supply (V_{PS2}), which is substantially lower than the first. In the illustrated embodiment, the first power supply may be an I/O supply and the second power supply may be a core supply.

As used herein, a “low voltage transistor” may be generally described as having a thinner gate oxide and/or different source/drain doping than a “high voltage transistor.” In addition, low voltage transistors tend to be smaller than their high voltage counterparts and are typically optimized for operating within a lower voltage range (e.g., about 0.0V to 1.45V for CMOS), depending on the particular process technology used. Unlike high voltage transistors, which are optimized for operating within a higher voltage range (e.g., about 0.0V to about 1.8V for CMOS), low voltage transistors often experience some level of degradation when gate-to-drain (or gate-to-source) voltages exceed the upper threshold of the operating range (e.g., about 1.45V). Therefore, high-voltage transistors may be needed in the signal path of the level shift circuit, while low-voltage transistors may be used for inverting the low swing input signals.

As shown in. 2, the gate and drain terminals of the PMOS pull-up transistors (MP1, MP2) are “cross-coupled” to one another. For example, the gate terminal of pull-up transistor MP1 is coupled to the drain terminal of pull-up transistor MP2 at the output (OUT) node of the level shift circuit. The gate terminal of pull-up transistor MP2 is similarly coupled to the drain terminal of pull-up transistor MP1 at the output (OUTB) node of the level shift circuit. For this reason, pull-up transistors (MP1, MP2) may be otherwise referred to herein as “cross-coupled transistors.”

Level shifted output signals (OUT, OUTB) are generated at the mutually-coupled drain terminals of the pull-up and pull-down transistors. In other words, the drain terminal of pull-up transistor MP1 is coupled to the drain terminal of pull-down transistor MN1 at the OUTB node. A similar connection between the drain terminals of pull-up transistor MP2 and pull-down transistor MN2 is made at the OUT node. Depending on the level of the input signals supplied to transistors MN1 and MN2, level shift circuit 200 may function to pull the output nodes: (i) up towards the first power supply voltage (V_{PS1}) by activating transistors MP1 and MP2, or (ii) down towards ground (V_{GND}) by activating transistors MN1 and MN2.

In one embodiment, the first power supply voltage (V_{PS1}) may be a relatively high voltage level (e.g., about 2.5V to about 5.0V) consistent with the high voltage transistors included within the I/O portion of an interface circuit. As such, level shift circuit 200 may be configured for translating relatively small swing internal signals (e.g., signals generated at core voltage levels) into relatively large swing external signals (e.g., signals usable in the I/O portions of the IC). However, one skilled in the art would understand how level shift circuit 200 could be modified to provide the opposite effect.

Level shift circuit 200 improves upon level shift circuit 100 by providing the following benefits. A rise propagation delay attributed to level shift circuit 200 (i.e., the time needed for the output signal to transition from a logic LOW state to a logic HIGH state) is reduced by increasing the size of pull-up transistor MP2 and decreasing the size of pull-up transistor MP1. Reducing the size of pull up transistor MP1 reduces the rise delay by enabling MN1 to pull the OUTB node down quicker. In one example, the rise delay may be reduced from about 1.3 ns to about 280 ps over the conventional solution. In one preferred embodiment, the size of the pull-up transistors may be adjusted to provide a rise delay, which is similar to the fall delay provided by the level shift circuit to reduce the amount of skew there between.

A fall propagation delay attributed to level shift circuit 200 (i.e., the time needed for the output signal to transition from a logic HIGH state to a logic LOW state) is reduced by adding feedback driver 210 (hereinafter referred to as a “pulse generator”) and feedback PMOS device MP3 (hereinafter referred to as a “feedback transistor”) to the level shift circuit. As described in more detail below, the pulse generator reduces the fall delay attributed to the level shift circuit by supplying a logic LOW, short duration pulse (hereinafter referred to as a “feedback pulse”) to the gate terminal of the feedback transistor. This reduces the fall delay by pulling the OUTB node up as quickly as possible. This increases the speed with which pull-up transistor MP2 is de-activated and the OUT node is discharged to ground (through pull-down transistor MN2). In one embodiment, the feedback circuit (comprising pulse generator 210 and feedback transistor MP3) may be configured for reducing the fall delay from about 1 ns to about 350 ps, when compared to the conventional solution shown in FIG. 1. As described in more detail below, a logic hold circuit 220 (hereinafter referred to as a “latch”) is added to prevent the feedback node (FB) from floating when the IN signal is logic HIGH.

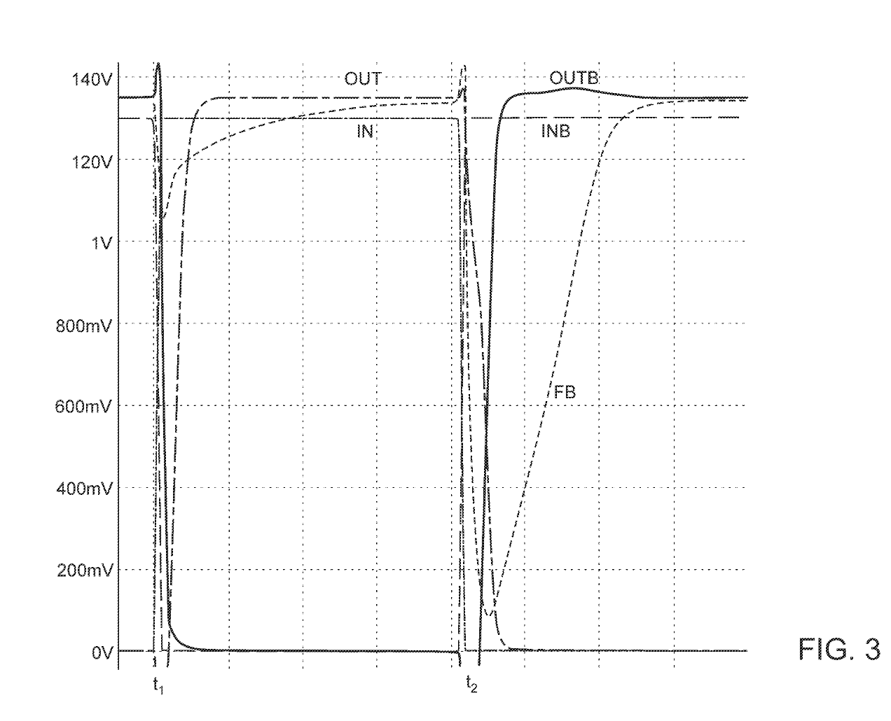

Referring to the exemplary graph of FIG. 3, the improved level shift circuit (200) operates in the following manner. In a first case, the input IN and output OUT signals transition from a logic LOW to a logic HIGH state, and the complementary input INB signal transitions from a logic HIGH to a logic LOW state. During this rising edge transition (shown, e.g., at time t1 in FIG. 3), pull-down transistor MN1 pulls node OUTB LOW, while node OUT is pulled HIGH by pull-up transistor MP2. At the same time, latch 220 forces the feedback signal (FB) to a logic HIGH state to prevent the feedback transistor (MP3) from turning ON, thus, enabling transistor MN1 to pull the OUTB node down as quickly as possible.

In a second case, the input IN and output OUT signals transition from a logic HIGH to a logic LOW state, and the complementary input INB signal transitions from a logic LOW to a logic HIGH state. During this falling edge transition (shown, e.g., at time t2 in FIG. 3), pull-down transistor MN2 pulls the OUT node LOW directly. To assist with the pull-down action, the feedback circuit is activated to pull the OUTB node HIGH as quickly as possible in order to de-activate pull-up transistor MP2. In other words, the feedback circuit provides a shorter falling edge delay by turning off pull-up device MP2 faster. To perform this function, the feedback circuit produces a LOW pulse of short duration (FB, as shown in FIG. 3) at the feedback node (i.e., the output terminal of the pulse generator), which turns off the pull up transistor MP2 faster. The latch 220 then serves to reset the feedback signal to a logic HIGH state in preparation for the next rising edge signal propagation.

In addition to improving fall delay, the feedback circuit is indirectly responsible for improving the rise delay associated with level shift circuit 200. For example, the feedback circuit enables pull-up transistor MP1 to be sized larger than the prior art by assisting the turn-off of MP2 during falling edge transitions. As noted above, decreasing the size of MP1 improves the rise delay of the level shift circuit by offering less resistance when transistor MN1 tries to pull-down the OUTB node.

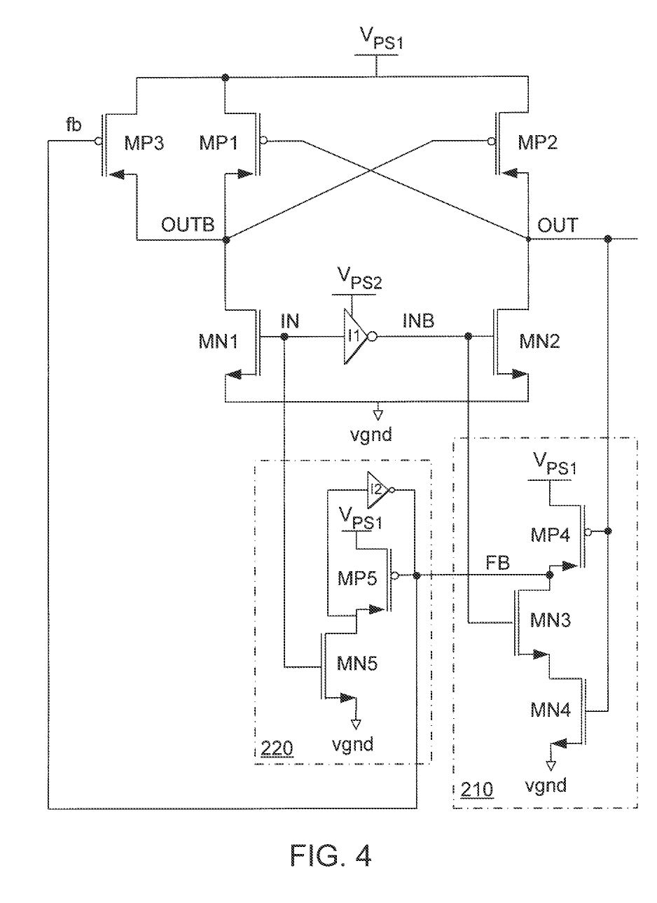

FIG. 4 illustrates one manner in which pulse generator 210 and latch 220 may be implemented in accordance with the invention. As shown in FIG. 4, pulse generator 210 includes three transistors (MP4, MN3, MN4) coupled in series between the first power supply (V_{PS1}) and ground (V_{GND}). In particular, transistor MP4 comprises a gate terminal coupled to the OUT node, a source terminal coupled to the first power supply (V_{PS1}) and a drain terminal coupled to the feedback node (FB). Transistor MN3 comprises a gate terminal coupled to the INB node, a drain terminal coupled to the feedback node (FB) and a source terminal coupled to the drain terminal of transistor MN4. Transistor MN4 comprises a gate terminal coupled to the OUT node, a drain terminal coupled to the source terminal of transistor MN3 and a source terminal coupled to ground (V_{GND}).

Pulse generator 210 operates in the following manner. When the INB signal transitions to a logic LOW state and the OUT signal transitions to a logic HIGH state, transistors MP4 and MN3 are turned OFF and transistor MN4 is turned ON. This discharges the source terminal of transistor MN3 to ground. When the INB signal transitions to a logic HIGH state and the OUT signal transitions to a logic LOW state, transistors MP4 and MN3 are turned ON and transistor MN4 is turned OFF. This produces a logic LOW feedback pulse (FB) at the drain terminal of transistor MN3, which is quickly reset by latch 220, as described in more detail below.

As shown in FIG. 4, latch 220 includes two transistors (MP5, MN5) coupled in series between the first power supply (V_{PS1}) and ground (V_{GND}), and an inverter (I2) coupled for resetting the feedback signal to a logic HIGH state shortly after the feedback pulse is generated. In particular, transistor MP5 comprises a gate terminal coupled to the output terminal of the pulse generator (i.e., to the feedback node, FB), a source terminal coupled to the first power supply (V_{PS1}) and a drain terminal coupled to the drain terminal of transistor MN5. Transistor MN5 comprises a gate terminal coupled to the IN node, a source terminal coupled to ground (V_{GND}) and a drain terminal coupled to the drain terminal of transistor MP5. Inverter I2 is coupled between the drain and gate terminals of transistor MP5.

Latch 220 operates in the following manner. When the IN and OUT signals transition to a logic LOW state, the feedback signal provided by pulse generator 210 is supplied to the gate terminals of feedback transistor MP3 and latch transistor MP5 as a logic LOW pulse. The duration of the feedback pulse is determined, at least in part, by the time delay between the rising edge of INB and the falling edge of OUT (this can be affected by the load at the OUT node), the drive strength of MN3 and MN4, and the capacitive load on the FB node. When the IN and OUT signals transition to a logic HIGH state, transistor MN5 turns ON pulling its drain to ground. The drain terminal voltage is inverted by inverter I2 and supplied to the gate terminals of feedback transistor MP3 and latch transistor MP5 as a logic HIGH signal. In this manner, latch 220 prevents the feedback node from floating (in an undefined state) when at least one of the IN and OUT signals is logic HIGH.

In summary, pulse generator 210 is included within level shift circuit 200 for “NANDing” the inverted input signal (INB) with the output signal (OUT). Latch 220 is included to complete the NAND by providing a pull-up function for the feedback path. When the IN signal transitions to a logic LOW state, the pulse generator sends a short duration logic low pulse (FB) to the gate terminal of the feedback transistor to pull the OUTB node up towards the first power supply voltage (V_{PS1}). This speeds up the fall transition by enabling the OUT node to discharge as quickly as possible. When the IN signal transitions to a logic HIGH state, the latch forces the feedback signal (FB) signal to logic HIGH to prevent the feedback node from floating and consuming static power.

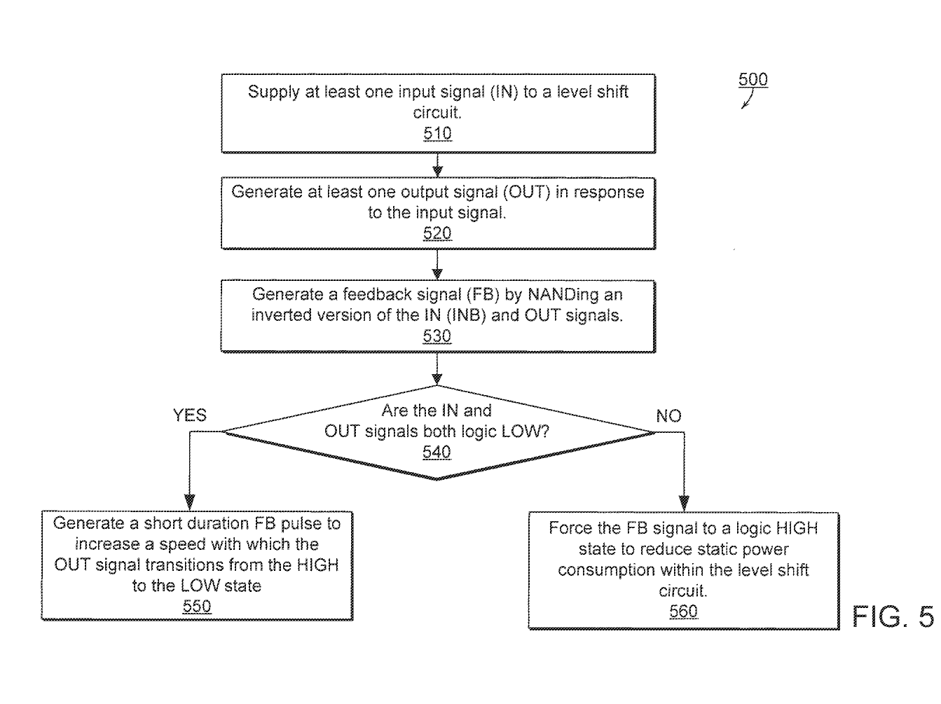

An exemplary method (500) for operating the improved level shift circuit (200) is shown in FIG. 5. According to one embodiment, the exemplary method for level shifting may include supplying an input signal (e.g., the IN signal shown in FIG. 2) to the level shift circuit (step 510) and generating an output signal (e.g., the OUT signal shown in FIG. 2) in response to the input signal (step 520). The method may also include generating a feedback signal by NANDing an inverted version of the input signal (e.g., the INB signal shown in FIG. 2) with the output signal (step 530).

During a first time period (YES branch of step 540), the input and output signals may transition from a logic HIGH state to a logic LOW state. According to a specific aspect of the invention, the speed with which the output signal transitions from HIGH to LOW may be increased by generating and supplying a short duration feedback pulse to a feedback transistor (e.g., MP3 of FIG. 2) of the level shift circuit (step 550). In general, the short duration feedback pulse may be adapted to deactivate a first pull-up transistor (e.g., MP2 of FIG. 2) of the level shift circuit faster by increasing a control voltage supplied thereto. This reduces a fall delay attributed to the level shift circuit by increasing the speed with which a first pull-down transistor (e.g., MN2 of FIG. 2) of the level shift circuit can pull the output signal to the logic LOW state.

During a second time period (NO branch of step 540), the input and output signals may transition from a logic LOW to a logic HIGH state. According to another specific aspect of the invention, the method may include forcing the feedback signal to the logic HIGH state when at least one of the output signal and the input signal is logic HIGH (step 560). This de-activates the feedback transistor, prevents a feedback node of the level shift circuit from floating in an undefined state and reduces static power consumption of the level shift circuit.

In some cases, the speed with which the output signal transitions from LOW to HIGH during the second time period may be increased (at least indirectly) by using the short duration feedback pulse to assist in pulling down the output signal during the first time period. In other words, using the short duration feedback pulse as noted above enables a size of the first pull-up transistor (e.g., MP2 of FIG. 2) to be substantially larger than the size of a second pull-up transistor (e.g., MP1 of FIG. 2) of the level shift circuit. Decreasing the size of the second pull-up transistor (e.g., MP1 of FIG. 2) enables the second pull-up transistor to pull the output signal up quicker during the second time period, thereby increasing the speed with which the output signal transitions from LOW to HIGH during the second time period.

One embodiment of an improved level shift circuit and method for level shifting has now been described herein. In general, the improved level shift circuit and method provide the benefits of reduced rise and fall propagation delays and reduced skew between rise/fall delays. In some cases, skew may be reduced by adjusting the size of the pull-up transistors (MP1, MP2) to more closely match the rise delay to the fall delay of the level shift circuit. In some cases, skew may be reduced by configuring the pulse generator and/or the latch, so as to more closely match the fall delay to the rise delay of the level shift circuit. In some cases, the pulse generator and latch may be appropriately configured to provide a fall delay, which is substantially equal to the rise delay provided by pull-up transistors of the same size. In other words, adjusting the size of pull-up transistors MP1 and MP2 may not be necessary in all embodiments of the invention.

In one application, the improved level shift circuit described herein may be incorporated within one or more interface circuits of an I/O portion of an integrated circuit (IC). One example of an integrated circuit (600) including one or more interface circuits is shown in FIG. 6. In the illustrated example, IC 600 includes two interface circuits (610, 620), one for translating I/O signal levels (e.g., Vin1, Vin2) to core signal levels (e.g., Vin1′, Vin2′) and one for translating core signal levels (e.g., Vout1a, Vout1b, Vout2) to I/O signal levels (e.g., Vout1a′, Vout1b′, Vout2′). However, one skilled in the art would recognize how the I/O portion of an IC may include more or less interface circuits for translating between substantially any number of signal levels.

In the example of FIG. 6, interface circuit 610 is coupled for receiving a pair of I/O signal levels (e.g., Vin1, Vin2), translating the I/O signal levels into core signal levels (e.g., Vin1′, Vin2′) and providing the translated signals to a plurality of internal circuit components (630). Although three are shown in the example of FIG. 6, one skilled in the art would recognize that more or less internal circuit components could be included without departing from the scope of the invention. In order to perform the necessary translation, interface circuit 610 may include a pair of level shift circuits (200), similar to the one shown in FIGS. 2-3. Each level shift circuit included within interface circuit 610 may be coupled for receiving a different one of the I/O signal levels (e.g., Vin1 or Vin2). In addition, the level shift circuits may be coupled for receiving the core and I/O power supplies for translating the I/O signal levels into core signal levels (e.g., Vin′ or Vin2′). The core power supply is illustrated in FIG. 6 as an external signal supplied to one of the input pins (640) of the IC. However, the core power supply is not limited to an externally generated supply, and may be generated within the IC in alternative embodiments of the invention. In addition, one skilled in the art would recognize how interface circuit 610 may be alternatively configured for translating between more or less than the two signal levels shown.

In the example of FIG. 6, interface circuit 620 is coupled for translating the output signals generated by the internal circuit components (630) from core signal levels (Vout1a, Vout1b, Vout2) to I/O signal levels (Vout1a′, Vout1b′, Vout2′). In order to perform the necessary translation, interface circuit 620 may include three level shift circuits (200), similar to the one shown in FIGS. 2-3. Each level shift circuit included within interface circuit 620 may be coupled for receiving a different one of the output signals (e.g., Vout1a, Vout1b or Vout2), as well as the core and I/O power supplies for translating the core signal levels into I/O signal levels (e.g., Vout1a′, Vout1b′ or Vout2′). The translated output signals (Vout1a′, Vout1b′, Vout2′) may then be supplied to output pins (650) of the integrated circuit. One skilled in the art would recognize how interface circuit 620 may be alternatively configured for translating between more or less than the three signal levels shown.

Embodiments of the present invention are well suited to performing various other steps or variations of the steps recited herein, and in a sequence other than that depicted and/or described herein. For purposes of clarity, many of the details of the improved solution and the methods of designing and manufacturing the same that are widely known and are not relevant to the present invention have been omitted from the following description.

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

Similarly, it should be appreciated that in the foregoing description of exemplary embodiments of the invention, various features of the invention are sometimes grouped together in a single embodiment, figure, or description thereof for the purpose of streamlining the disclosure, and thus, aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects may lie in less than all features of a single foregoing disclosed embodiment. Thus, the claims following the detailed description are hereby expressly incorporated into this detailed description, with each claim standing on its own as a separate embodiment of this invention.

What is claimed is:

1. A level shift circuit, comprising:
a feedback transistor coupled for receiving a feedback pulse to activate the feedback transistor, and as a consequence, reduce a fall delay associated with the level shift circuit; and
a pulse generator coupled to the feedback transistor and configured for generating the feedback pulse only when an input signal and an output signal of the level shift circuit are both logic low.

2. The level shift circuit as recited in claim 1, further comprising:
a first input transistor coupled in series with a first cross-coupled transistor between a power supply and a ground supply, wherein the first input transistor is configured for receiving a first input signal supplied to the level shift circuit;
a second input transistor coupled in series with a second cross-coupled transistor between the power supply and the ground supply, wherein the second input transistor is configured for receiving a second input signal supplied to or produced by the level shift circuit; and
an output node arranged between the second input transistor and the second cross-coupled transistor for receiving the output signal.

3. The level shift circuit as recited in claim 2, wherein a rise delay associated with the level shift circuit is reduced by configuring the first and second cross-coupled transistors, such that the first cross-coupled transistor is substantially smaller than the second cross-coupled transistor.

4. The level shift circuit as recited in claim 2, wherein the pulse generator comprises:
a pair of input terminals coupled to a control terminal of the second input transistor and to the output node for receiving the second input signal and the output signal, respectively; and
an output terminal, which is coupled to a control terminal of the feedback transistor for supplying the feedback pulse thereto.

5. The level shift circuit as recited in claim 4, wherein the pulse generator is configured for asserting the feedback pulse, and thus, activating the feedback transistor only when the output signal and the first input signal are both logic low and the second input signal is logic high.

6. The level shift circuit as recited in claim 5, further comprising a latch coupled between a control terminal of the first input transistor and the output terminal of the pulse generator for deasserting the feedback pulse, and thus, deactivating the feedback transistor when at least one of the output signal and the first input signal is logic high.

7. The level shift circuit as recited in claim 6, wherein the pulse generator comprises:
a first, a second and a third pulse generator transistor coupled in series between the power supply and the ground supply; and
the output terminal, which is arranged between the first and second pulse generator transistors for receiving the feedback pulse generated there between.

8. The level shift circuit as recited in claim 7, wherein:
control terminals of the first and third pulse generator transistors are coupled for receiving the output signal; and
a control terminal of the second pulse generator transistor is coupled for receiving the second input signal.

9. The level shift circuit as recited in claim 7, wherein the latch comprises:
a first latch transistor coupled in series with a second latch transistor between the power supply and the ground supply; and
an inverter having an input coupled between the first and second latch transistors, and an output coupled to the output terminal of the pulse generator.

10. The level shift circuit as recited in claim 9, wherein:
a control terminal of the first latch transistor is coupled to the output terminal of the pulse generator; and
a control terminal of the second latch transistor is coupled to the control terminal of the first input transistor.

11. The level shift circuit as recited in claim 9, wherein:
the first and second input transistors comprise NMOS transistors;
the first and second cross-coupled transistors comprise PMOS transistors;
the feedback transistor comprises a PMOS transistor;
the first pulse generator transistor comprises a PMOS transistor;
the second and third pulse generator transistors comprise NMOS transistors;
the first latch transistor comprises a PMOS transistor; and
the second latch transistor comprises an NMOS transistor.

12. A method for level shifting, the method comprising:
supplying an input signal to a level shift circuit, wherein the input signal transitions from a logic high state to a logic low state during a first time period;
generating an output signal within the level shift circuit, wherein the output signal transitions from the logic high state to the logic low state in response to the input signal supplied during the first time period; and
generating a short duration pulse within the level shift circuit to increase a speed with which the output signal transitions from the logic high state to the logic low state.

13. The method as recited in claim 12, wherein the short duration pulse is adapted to increase a control voltage supplied to a pull-up transistor of the level shift circuit for deactivating the pull-up transistor faster, thereby increasing the speed with which a pull-down transistor of the level shift circuit can pull the output signal from the logic high state to the logic low state.

14. The method as recited in claim 12, wherein the method further comprises:
generating a feedback signal by NANDing the output signal with an inverted version of the input signal; and
supplying the feedback signal to a control terminal of a feedback transistor coupled to a control terminal of the pull-up transistor.

15. The method as recited in claim 14, wherein the step of generating a feedback signal comprises generating the short duration pulse only when the output signal and the input signal are both logic low.

16. The method as recited in claim 15, the method further comprising:
supplying the input signal to the level shift circuit, wherein the input signal transitions from the logic low state to the logic high state during a second time period;
generating the output signal within the level shift circuit, wherein the output signal transitions from the logic low state to the logic high state in response to the input signal supplied during the second time period; and
forcing the feedback signal to the logic high state when at least one of the output signal and the input signal are logic high.

17. An integrated circuit comprising:
an interface circuit configured for converting a first signal level into a second signal level, which is substantially different from the first signal level, wherein the interface circuit includes at least one level shift circuit comprising:
a pair of pull-down transistors, at least one of which is coupled for receiving an input signal at the first signal level;
a pair of pull-up transistors, each coupled in series with a different one of the pair of pull-down transistors between a first power supply and ground;
an output node arranged between one of the serially-coupled pull-up and pull-down transistors for generating an output signal at the second signal level;
a feedback transistor coupled for reducing a fall delay associated with the level shift circuit by receiving a short duration pulse, which is adapted to deactivate one of the pull-up transistors faster; and
a pulse generator coupled to the feedback transistor and configured for generating the short duration pulse only when the input signal and the output signal are both logic low.

18. The integrated circuit as recited in claim 17, wherein the level shift circuit further comprises a latch coupled for supplying a logic high signal to the feedback transistor when at least one of the input signal and the output signal is logic high.

19. The integrated circuit as recited in claim 18, wherein the first power supply comprises a voltage level selected from a range comprising about 1.2 V to about 2.5V, and wherein the second signal level is substantially less than the first signal level.

20. The integrated circuit as recited in claim 19, wherein the integrated circuit comprises a plurality of integrated circuit components, at least one of which is: (i) coupled to the level shift circuit for receiving the output signal at the second signal level, and (ii) coupled to the first power supply.

21. The integrated circuit as recited in claim 18, wherein the first power supply comprises a voltage level selected from a range comprising about 2.5 V to about 5.0V, and wherein the second signal level is substantially greater than the first signal level.

22. The integrated circuit as recited in claim 21, wherein the integrated circuit comprises a plurality of integrated circuit components, at least one of which is: (i) coupled for supplying the input signal to the level shift circuit at the first signal level, and (ii) coupled to a second power supply, whose voltage level is selected from a range comprising about 1.2 V to about 2.5V.
